(19) United States
(12) Patent Application Publication
(10) Pub. No.: US 2026/0038773 A1
(43) Pub. Date: Feb. 5, 2026

(54) Hybrid Plasma-Enhanced Atomic Layer Etching (PEALE) And Plasma-Enhanced Atomic Layer Deposition (PEALD) In A Single Reactor/Chamber

(71) Applicant: Nano-Master, Inc., Austin, TX (US)

(72) Inventor: Birol Kuyel, Austin, TX (US)

(21) Appl. No.: 19/279,251

(22) Filed: Jul. 24, 2025

Related U.S. Application Data
(60) Provisional application No. 63/678,728, filed on Aug. 2, 2024.

(51) Int. Cl. H01J 37/32; C23C 16/455

(52) U.S. Cl. CPC H01J 37/32449; C23C 16/45536; C23C 16/45553; H01J 37/321; H01J 37/32174; H01J 37/32633; H01J 37/32724; H01J 2237/3321; H01J 2237/3323; H01J 2237/3341

(57) ABSTRACT

Techniques are disclosed for methods and apparatus for performing plasma-enhanced atomic layer etching (PEALE) as well as plasma-enhanced atomic layer deposition (PEALD) in a single hybrid reactor. Depending on the configuration of the hybrid reactor, two modes of PEALE are supported. The first mode is mode A PEALE in which plasma is used both during the modification and removal steps of ALE. The second mode is mode B PEALE in which plasma is not used in the removal step of ALE and in which the removal/etching is carried out entirely in the thermal regime. The design allows one to perform ALE for cleaning the substrate surface by removing any surface layer including native oxides prior to performing ALD in the same chamber, and thus without breaking the vacuum and potentially re-oxidizing the surface.

### RELATED APPLICATIONS

This application claims priority from U.S. Provisional Patent Application No. 63/678,728 filed on Aug. 2, 2024, and which is incorporated by reference herein for all purposes in its entirety. This application is also related to U.S. patent application Ser. No. 15/458,642, now U.S. Pat. No. 9,972,501 B1 issued on May 15, 2018 and U.S. patent application Ser. No. 16/738,240, now U.S. Pat. No. 11,087,959 B2 issued on Aug. 10, 2021. All the above-numbered patent applications and patents are incorporated by reference herein for all purposes in their entireties.

### FIELD OF THE INVENTION

This invention generally relates to atomic layer etching (ALE) of a substrate surface and to atomic layer deposition (ALD) of a uniform film on the substrate surface for protection or building of semiconductor devices. More specifically, this invention is related to performing ALE and ALD in a single reactor/chamber.

### BACKGROUND ART

Atomic layer etching (ALE) is a technique for precisely removing material one atomic layer at a time, using self-limiting reactions. It typically involves alternating steps of chemisorption i.e. modifying the top atomic layer to make it reactive, for example by Cl2, F2, O2. This is followed by desorption/removal i.e. using ions, plasma, or another reactant to sputter off or to remove the modified layer. Each cycle removes only a single atomic layer. By repeating the cycles, one gets etching with atomic-scale accuracy usually with sub-nanometer etch control. Plasma-Assisted Atomic Layer Etching (PAALE) is a type of ALE that uses a plasma source (e.g. Ar) to assist one or both steps of the ALE cycle.

Atomic layer deposition (ALD) utilizes a sequential exposure of gaseous reactants for the deposition of atomically sized thin films. The reactants are often metal precursors consisting of organometallic liquids or solids used in the chemistry by vaporizing under vacuum and/or heat conditions. The reactants are introduced as a series of sequential, non-overlapping pulses. In each of these pulses, the reactant molecules react with a substrate or wafer surface in a self-limiting way. Consequently, the reaction ceases once all the reactive sites on the wafer/substrate surface are consumed. Between the two pulses, a purge step is applied to remove the excess reactants and byproducts from the process chamber. Using ALD, it is possible to grow materials uniformly and with high precision on arbitrarily complex and large substrates. Some examples of films produced using ALD are SiO2, Si3N4, Ga2O3, GaN, Al2O3, AlN, etc.

More generally, there are no designs that exist that would allow one to perform both ALD and ALE in the same reactor/chamber. Despite the useful aspect of plasma ions that are used to sputter off the modified layer, there is the potential of damaging the device being fabricated by unwanted ion bombardment. Therefore, in an ideal ALE regime, plasma-activated radicals would be used for removing the modified layer while still minimizing or avoiding the damage to the device by potential ion bombardment. However, to date, no such design of a reactor or process exists that would bring the substrate surface to its pristine/virgin condition for subsequent ALD operation, while still avoiding damage to the device by ion bombardment during ALE. To summarize, no design exists to date that would allow one to perform both ALD and ALE in the same reactor. Furthermore, no design exists that would allow one to perform both ALD and ALE in the same reactor and without ion bombardment.

Some prior attempts perform etching of the native oxide (SiO2) in one chamber and then taking the substrate to an ALD chamber for film deposition. However, this is ineffectual because native oxide regrows or the surface re-oxidizes during the transfer in atmosphere before the ALD deposition can take place. Furthermore, the surface can also acquire other contaminants and particles as a surface layer during the transfer. The present invention solves the above problems in the prior art as provided by the below disclosure.

### OBJECTS OF THE INVENTION

In view of the shortcomings of the prior art, it is an object of the present invention to provide methods and apparatus/systems for performing both plasma-enhanced atomic layer etching (PEALE) as well as plasma-enhanced atomic layer deposition (PEALD) in a single hybrid reactor, and without breaking the vacuum.

It is also an object of the invention to effectively remove the surface layer, including native oxides from the substrate surface by PEALE and to bring it to its pristine or virgin state before performing PEALD.

It is another object of the invention to perform PEALE in which plasma is using both for the modification and removal steps of the ALE.

It is another object of the invention to perform PEALE in which plasma is only used in the modification step but not in the removal step of the ALE.

It is further an object of the invention to repeat the modification and removal steps of ALE for as many cycles as needed to achieve a desired thickness or thinness of the surface layer.

While performing PEALD, it is another object of the present hybrid design to produce high quality/uniformity films by preventing the flow of damaging plasma flux from entering into the ALD volume.

While performing PEALD, it is yet another object of the present hybrid design to have a continuous-flow of precursor gases into the chamber throughout the deposition process.

Still other objects and advantages of the invention will become apparent upon reading the detailed description in conjunction with the drawing figures.

### SUMMARY

The objects and advantages of the present technology are secured by methods and apparatus/systems for performing atomic layer etching (ALE) and atomic layer deposition (ALD) in a single ALE-ALD or ALE/ALD hybrid reactor. Since the ALE and ALD are plasma-enhanced, they may be referred to as PEALE and PEALD respectively and the hybrid reactor of the instant design may be referred to as a PEALE-PEALD reactor. The ALE is performed before commencing ALD and its purpose is to clean the surface of impurities including oxides or any other contaminants that may negatively affect the quality of the ALD film(s)/layer(s) deposited later.

We will refer to such layers of impurities including oxides of silicon or any other oxides or any other unwanted chemical species simply as surface layer. More generally, the term ‘surface layer’ as used herein refers to any layer, film, residue, deposit, or accumulation on the surface of a substrate, including but not limited to native oxides, adsorbed molecular species, metallic impurities, polymer films, plasma-damaged layers or naturally formed films. Removal of surface layer effectively brings the substrate to its pristine or virgin state.

The instant reactor comprises of a cylindrical chamber that has an upper portion and a lower portion such that the upper portion and the lower portion can be closed to obtain a pneumatically sealed state of the reactor or chamber. The upper portion includes a planar inductively coupled plasma (ICP) source that is laterally affixed at its far or distal end from the lower portion. The silicon substrate or wafer is placed on top of a platen in the lower portion that may be heated by a platen heater to a desired temperature during the operation of the reactor. Of course, during the operation, the upper and lower portions of the chamber are closed to obtain the above-mentioned sealed state of the chamber.

According to the instant principles, the substrate is isolated from the ICP source in the chamber by a metal plate that is laterally affixed above the substrate as well as a ceramic plate that is laterally affixed below the metal plate but above the substrate. The metal plate is isolated from the electrical ground by a ceramic ring spacer. The metal plate and the ceramic plate have a first plurality of holes and a second plurality of holes respectively such that each of the first plurality of holes is aligned with a corresponding hole of the second plurality of holes. Each of the second plurality of holes of the ceramic plate has a diameter less than two Debye lengths of a plasma that is generated above the metal plate by the ICP source.

The ALE phase in the instant hybrid reactor is performed using two steps: a modification step, and a removal/etching step. Each of the steps is performed for a desired duration of time. Two modes of PEALE are supported in the instant design that differ in how the second or the removal step is performed. In one mode of the PEALE, i.e. mode A, plasma is used both for the modification and removal steps of the ALE. In the second mode, i.e. mode B of instant PEALE, plasma is only used in the modification step but not in the removal step of the ALE. Instead, it is thermal energy that is used in the removal step of the ALE in mode B.

In order to perform either mode A or mode B of ALE, first a modification step of ALE is performed by providing a radio frequency (RF) signal to the ICP source and then flowing a plasma-forming or precursor gas to the ICP source to form the above-mentioned plasma. We refer to this RF signal as ICP RF signal. The ICP RF signal has a frequency of 13.56 MHz and its power is selected to suit the needs of a given application. Exemplarily, the power of ICP RF signal during this first or modification step of the ALE is in the range 150 watts to 1000 watts.

Simultaneously to this first ICP RF signal, a modifying gas is also flowed to the ICP source. Both the precursor gas and the modifying gas may comprise of one or more individual chemical species. As a result, activated radicals of the modifying gas enter through the first plurality of holes of the metal plate and then through the second plurality of holes of the ceramic plate. They, then enter into the space around the substrate, referred to as the process volume. There the activated radicals of the modifying gas react or nucleate with the surface layer on the substrate to form a nucleated layer on the substrate. Per above, the modification step is performed for a desired duration of time.

Subsequently, a removal/etching step of ALE is performed, also for a desired duration of time. In mode A ALE embodiments, the removal step is performed for the desired duration. This is accomplished by switching off the first ICP RF signal to the ICP source, and by applying a low-power or minimum/minimal-power RF signal to the metal plate and also applying another or the same low-power RF signal to the platen. Simultaneously, a precursor gas is flowed to the ICP source, which also enters the process volume through the two plurality of holes of the metal plate and the ceramic plate. Ions of the low-density plasma in the process volume sputter off the nucleated layer from the substrate and as result, removes or reduces the surface layer on the substrate. The modification step and the etching step of ALE are repeated in sequence until a desired thickness or thinness or a desired reduction of the surface layer on the substrate has been achieved. The cycle-time of mode A ALE is the sum of the above-mentioned durations of the modification and removal steps.

In the mode B ALE embodiments, the removal step is performed for a desired duration by switching off the first ICP RF signal to the ICP source and by simultaneously pulsing trimethylaluminum (TMA) into the process volume to etch the nucleated layer. Unlike the embodiments of mode A, where the precursor gas ions sputter off the nucleated layer, in the present mode B ALE embodiments, TMA reacts with the nucleated later entirely in the thermal regime. In other words, there is no plasma at all in the process volume during the removal step of the present mode B embodiments. In the present embodiments, the possibility of plasma ion damage to the substrate or to the device being manufactured is thus completely eliminated during the removal step.

Thus, during the removal step in mode B, TMA is activated entirely thermally to react with and remove the nucleated layer on the substrate. Preferably, the thermal regime is carried out at substantially 200° C. This shows that the present design allows thermal activation of TMA to occur at conveniently low temperatures. The cycle-time of the mode B ALE is the sum of the above-mentioned durations of the modification and removal steps.

Once the substrate surface has been sufficiently cleaned, the ALD phase is commenced. This is accomplished by providing the same or another ICP RF signal to the ICP source. Typically, this second ICP RF signal is provided at maximum power for maximal activation of species for ALD by the high-density plasma. Simultaneously to the ICP RF signal, a precursor gas is now continuously flowed to the ICP source to continuously generate the plasma and which enters the process volume through the above-described two plurality of holes. Further, a metal precursor, which may comprise of one or more chemical species, is also pulsed into the process volume. For the PEALD operation, the metal plate is now electrically grounded by suitably timed electrical switching. The metal plate, now grounded, terminates the plasma and prevents the ion flux from entering the process volume and from damaging the substrate.

Consequently, excited neutrals of the precursor gas, the metal precursor and the substrate react in a self-limiting manner to produce a uniform ALD film on the substrate. As a result, remarkably uniform films with little or no hydrogen content are produced by the instant PEALD. Furthermore, instant PEALD techniques do not require ammonia (NH3) for nitridation, so expensive downstream ammonia abatement activities are also avoided.

The diameter of the first plurality of holes in the metal plate is preferably ⅛ inches. However, the number of holes is far lesser than a typical dense showerhead design of the traditional art. In comparison, the corresponding holes of the ceramic plate are much smaller, preferably less than two Debye lengths of the plasma. The plasma field is shorted by the metal plate because it is grounded for PEALD. But the excited radicals, terminated by the metal plate, pass through its holes as neutral atoms/molecules. The high energy plasma flux consisting of plasma ions and electrons is prevented from entering the ALD volume by the ceramic plate while only the excited neutrals pass through. This is only possible because of the above-mentioned design of the ceramic plate holes having diameter less than two Debye lengths.

As many pulses of the precursor gas may be passed in as many ALD cycles as desired to incur a required thickness of the deposited film. More specifically, as many ALD cycles are performed as needed to obtain a film of a desired thickness. Preferably, the precursor is passed on a carrier gas. Preferably, the plasma comprises one or more of nitrogen, argon, oxygen and hydrogen. Preferably, the precursor comprises a metal precursor and the ALD film deposited is that of an oxide or a nitride of a metal. Preferably, the precursor is of a metal such as aluminum (Al), gallium (Ga), silicon (Si), zinc (Zn), hafnium, etc. and carried on an appropriate carrier gas. The carrier gas may be nitrogen (N2) or argon (Ar). Preferably, the deposited film is one of AlN, Al2O3, GaN, Ga2O3, SiO2, Si3N4, ZnO, Zn3N2, HfO2, etc.

In addition to the mechanical efficiencies of seamless switching between PEALE and PEALD afforded by the instant hybrid design, the economic efficiencies are also significant. Exemplarily, if the substrate is transferred from an ALE reactor to a different ALD chamber as in traditional art, the substrate surface can get contaminated or oxidized in the atmosphere. To address this issue, a very expensive robotic load lock system is generally required. The present design circumvents these problems of the prior art by providing a single hybrid ALE-ALD reactor.

In the preferred embodiment, the modifying/modification gas used in ALE is carbon tetrafluoride (CF4). As a consequence, the nucleated layer on the substrate comprises of silicon tetrafluoride (SiF4). Alternatively, the modification gas used is carbon tetrachloride (CCl4). As a consequence, the nucleated layer on the substrate comprises of silicon tetrachloride (SiCl4). In the same or related embodiments, the first and/or the second ICP RF signal applied to the ICP is in the range of 150 watts to 1000 watts. In the same or related embodiments, the low-power RF signal applied to the metal plate and to the platen is in the range of 20 watts to 100 watts, although the power for the low-power RF signal may be selected to suit the needs of a given application.

In the same or related embodiments, the duration of the modification and removal steps of mode A of ALE is 4 seconds each while the duration of the modification and removal steps of mode B of ALE is 3 seconds each. This results in ALE cycle-time of mode A and mode B of 8 seconds and 6 seconds respectively. The modification and removal steps of mode A ALE are preferably repeated 30 times in sequence or differently said, the mode A ALE phase is performed for 30 cycles. The modification and removal steps of mode B ALE are preferably repeated 50 times in sequence or differently said, the mode B ALE phase is performed for 50 cycles.

The methods of the present technology allow performing atomic layer etching (ALE) and atomic layer deposition (ALD) in a chamber, said method comprising the steps of: (a) placing a substrate atop a platen inside said chamber, said chamber having a planar inductively coupled plasma (ICP) source laterally affixed at its distal end from said substrate; (b) isolating said substrate from said ICP source in said chamber by a metal plate laterally affixed above said substrate and a ceramic plate laterally affixed below said metal plate but above said substrate, said metal plate and said ceramic plate having a first plurality of holes and a second plurality of holes respectively such that each of said first plurality of holes is aligned with a corresponding hole of said second plurality of holes, wherein each of said second plurality of holes is designed to have a diameter less than two Debye lengths of a plasma generated by said ICP source above said metal plate; (c) isolating said metal plate from an electrical ground by a ceramic ring spacer; (d) heating said platen, thereby heating said substrate to a desired temperature; (e) performing a modification step of said ALE for a first duration by providing a first ICP radio frequency (RF) signal to said ICP source and flowing a precursor gas to said ICP source to form said plasma, and flowing a modifying gas to said ICP source so that activated radicals of said modifying gas enter through said first plurality of holes and through said second plurality of holes into a process volume around said substrate, wherein said activated radicals of said modifying gas react with a surface layer on said substrate and form a nucleated layer on said substrate, and wherein each of said precursor gas and said modifying gas comprise one or more individual chemical species; (f) performing an etching step of said ALE for a second duration by stopping said first ICP RF signal to said ICP source, applying a first low-power RF signal to said metal plate and by applying a second low-power RF signal to said platen, and pulsing said precursor gas to said ICP source so that ions from said precursor gas sputter off said nucleated layer from said substrate in said process volume; (g) repeating said modification step (e) and said etching step (f) in sequence until a desired thickness of said surface layer on said substrate is achieved; (h) performing said ALD by providing a second ICP RF signal to said ICP source and continuously flowing said precursor gas to said ICP source to continuously generate said plasma, and grounding said metal plate to terminate said plasma and pulsing a metal precursor into said process volume, said metal precursor comprising one or more individual chemical species, whereby excited neutrals of said precursor gas, said metal precursor and said substrate react in a self-limiting manner to produce a substantially uniform ALD film on said substrate.

The methods of the present technology further allow performing atomic layer etching (ALE) and atomic layer deposition (ALD) in a chamber, said method comprising the steps of: (a) placing a substrate atop a platen inside said chamber, said chamber having a planar inductively coupled plasma (ICP) source laterally affixed at its distal end from said substrate; (b) isolating said substrate from said ICP source in said chamber by a metal plate laterally affixed above said substrate and a ceramic plate laterally affixed below said metal plate but above said substrate, said metal plate and said ceramic plate having a first plurality of holes and a second plurality of holes respectively such that each of said first plurality of holes is aligned with a corresponding hole of said second plurality of holes, wherein each of said second plurality of holes is designed to have a diameter less than two Debye lengths of a plasma generated by said ICP source above said metal plate; (c) isolating said metal plate from an electrical ground by a ceramic ring spacer; (d) heating said platen, thereby heating said substrate to a desired temperature; (e) performing a modification step of said ALE for a first duration by providing a first ICP radio frequency (RF) signal to said ICP source and flowing a precursor gas to said ICP source to form said plasma, and flowing a modifying gas to said ICP source so that activated radicals of said modifying gas enter through said first plurality of holes and through said second plurality of holes into a process volume around said substrate, wherein said activated radicals of said modifying gas react with a surface layer on said substrate and form a nucleated layer on said substrate, and wherein each of said precursor gas and said modifying gas comprise one or more individual chemical species; (f) performing an etching step of said ALE for a second duration by stopping said first ICP RF signal to said ICP source and by pulsing trimethylaluminum (TMA) into said process volume to etch said nucleated layer; (g) repeating said modification step (d) and said etching step (e) in sequence until a desired thickness of said surface layer on said substrate is achieved; (h) performing said ALD by providing a second ICP RF signal to said ICP source and continuously flowing said precursor gas to said ICP source to continuously generate said plasma, and grounding said metal plate to terminate said plasma and pulsing a metal precursor into said process volume, said metal precursor comprising one or more individual chemical species, whereby excited neutrals of said precursor gas, said metal precursor and said substrate react in a self-limiting manner to produce a substantially uniform ALD film on said substrate.

The apparatus of the present design include a system for performing atomic layer etching (ALE) and atomic layer deposition (ALD), said system comprising: (a) a cylindrical chamber comprising an upper portion and a lower portion such that said upper portion and said lower portion are closed to obtain a sealed state of said chamber; (b) said upper portion comprising a planar inductively coupled plasma (ICP) source laterally affixed at its distal end from said lower portion; (c) a substrate placed atop a platen in said lower portion and heated by a platen heater to a desired temperature; and (d) said substrate isolated from said ICP source in said chamber by a metal plate laterally affixed above said substrate and a ceramic plate laterally affixed below said metal plate but above said substrate, said metal plate isolated from an electrical ground, and said metal plate and said ceramic plate having a first plurality of holes and a second plurality of holes respectively such that each of said first plurality of holes is aligned with a corresponding hole of said second plurality of holes, and each of said second plurality of holes having a diameter less than two Debye lengths of a plasma generated above said metal plate by said ICP source; wherein a modification step of said ALE is performed for a first duration by providing a first ICP radio frequency (RF) signal to said ICP source and flowing a precursor gas to said ICP source to form said plasma, and flowing a modifying gas to said ICP source so that activated radicals of said modifying gas enter through said first plurality of holes and through said second plurality of holes into a process volume around said substrate, wherein said activated radicals of said modifying gas react with a surface layer on said substrate and form a nucleated layer on said substrate, and wherein each of said precursor gas and said modifying gas comprise one or more individual chemical species; and wherein an etching step of said ALE is performed for a second duration by stopping said first ICP RF signal to said ICP source, applying a first low-power RF signal to said metal plate and by applying a second low-power RF signal to said platen, and pulsing said precursor gas to said ICP source so that ions from said precursor gas sputter off said nucleated layer from said substrate in said process volume; and wherein said modification step and said etching step are repeated in sequence until a desired thickness of said surface layer on said substrate is achieved; and wherein said ALD is performed by providing a second ICP RF signal to said ICP source and continuously flowing said precursor gas to said ICP source to continuously generate said plasma, and grounding said metal plate to terminate said plasma and pulsing a metal precursor into said process volume, said metal precursor comprising one or more individual chemical species, wherein excited neutrals of said precursor gas, said metal precursor and said substrate react in a self-limiting manner to produce a substantially uniform ALD film on said substrate.

The apparatus of the present technology further include a system for performing atomic layer etching (ALE) and atomic layer deposition (ALD), said system comprising: (a) a cylindrical chamber comprising an upper portion and a lower portion such that said upper portion and said lower portion are closed to obtain a sealed state of said chamber; (b) said upper portion comprising a planar inductively coupled plasma (ICP) source laterally affixed at its distal end from said lower portion; (c) a substrate placed atop a platen in said lower portion and heated by a platen heater to a desired temperature; and (d) said substrate isolated from said ICP source in said chamber by a metal plate laterally affixed above said substrate and a ceramic plate laterally affixed below said metal plate but above said substrate, said metal plate isolated from an electrical ground, and said metal plate and said ceramic plate having a first plurality of holes and a second plurality of holes respectively such that each of said first plurality of holes is aligned with a corresponding hole of said second plurality of holes, and each of said second plurality of holes having a diameter less than two Debye lengths of a plasma generated above said metal plate by said ICP source; wherein a modification step of said ALE is performed for a first duration by providing a first ICP radio frequency (RF) signal to said ICP source and flowing a precursor gas to said ICP source to form said plasma, and flowing a modifying gas to said ICP source so that activated radicals of said modifying gas enter through said first plurality of holes and through said second plurality of holes into a process volume around said substrate, wherein said activated radicals of said modifying gas react with a surface layer on said substrate and form a nucleated layer on said substrate, and wherein each of said precursor gas and said modifying gas comprise one or more individual chemical species; and wherein an etching step of said ALE is performed for a second duration by switching off said first ICP RF signal to said ICP source and by pulsing trimethylaluminum (TMA) into said process volume to etch said nucleated layer from said substrate in said process volume; and wherein said modification step and said etching step are repeated in sequence until a desired thickness of said surface layer on said substrate is achieved; and wherein said ALD is performed by providing a second ICP RF signal to said ICP source and continuously flowing said precursor gas to said ICP source to continuously generate said plasma, and grounding said metal plate to terminate said plasma and pulsing a metal precursor into said process volume, said metal precursor comprising one or more individual chemical species, wherein excited neutrals of said precursor gas, said metal precursor and said substrate react in a self-limiting manner to produce a substantially uniform ALD film on said substrate.

Clearly, the systems and methods of the invention find many advantageous embodiments. The details of the invention, including its preferred embodiments, are presented in the below detailed description with reference to the appended drawing figures.

### BRIEF DESCRIPTION OF THE DRAWING FIGURES

FIG. 1 is a cross-sectional view of the hybrid PEALE-PEALD reactor/chamber of the instant design. Also shown in dotted and dashed lines is a rear perspective of the various ports and lines of the chamber.

FIG. 2 is a variation of FIG. 1 explicitly showing an RF port for providing an RF signal to the platen.

FIG. 3 shows the results of a mode A PEALE experiment in which the thickness of the native oxide layer is substantially reduced.

FIG. 4 shows the results of a mode A PEALE-PEALD experiment in which a PEALD film is deposited on a substrate on which the thickness of the native oxide layer had been substantially reduced by a prior ALE phase.

FIG. 5A shows a Transmission Electron Microscope (TEM) image of a very thin oxide layer visible before commencing PEALE.

FIG. 5B shows a TEM image after PEALE and PEALD have been performed in the same instant chamber. The image shows only the thick Si3N4 PEALD layer deposited on the Si wafer after the native oxide layer had been etched off by instant PEALE.

FIG. 6A shows SiO2 and Si curves obtained by X-ray Photoelectron Spectroscopy (XPS) before performing PEALE in an experiment.

FIG. 6B shows the SiO2 and Si curves obtained by XPS after mode B PEALE has been performed.

### DETAILED DESCRIPTION

The figures and the following description relate to preferred embodiments of the present invention by way of illustration only. It should be noted that from the following discussion, alternative embodiments of the structures and methods disclosed herein will be readily recognized as viable alternatives that may be employed without departing from the principles of the claimed invention.

Reference will now be made in detail to several embodiments of the present invention(s), examples of which are illustrated in the accompanying figures. It is noted that wherever practicable, similar or like reference numbers may be used in the figures and may indicate similar or like functionality. The figures depict embodiments of the present invention for purposes of illustration only. One skilled in the art will readily recognize from the following description that alternative embodiments of the structures and methods illustrated herein may be employed without departing from the principles of the invention described herein.

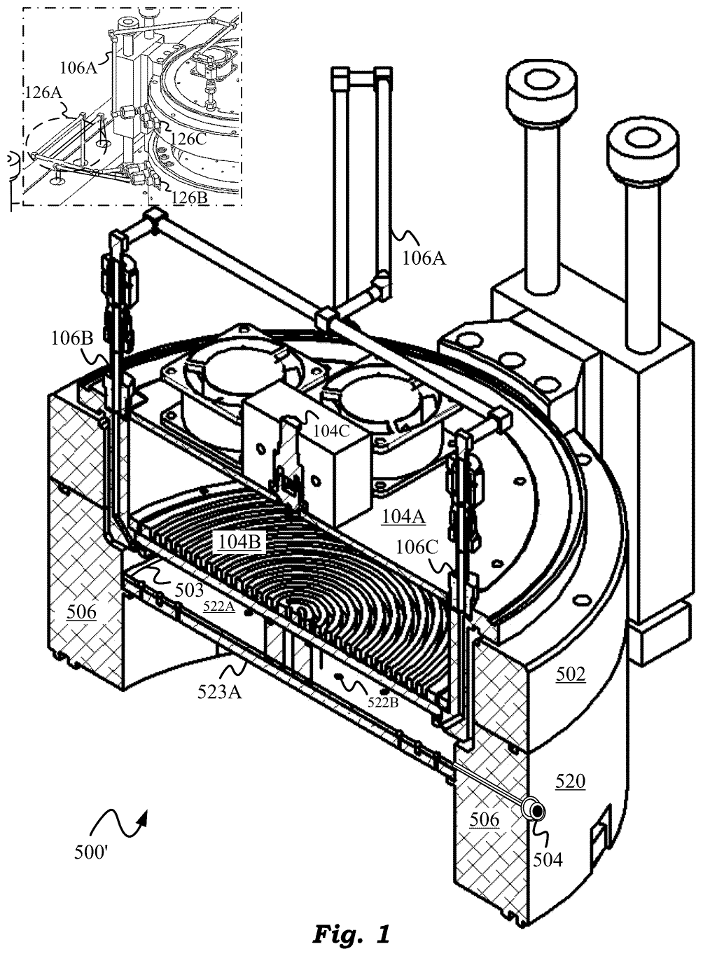

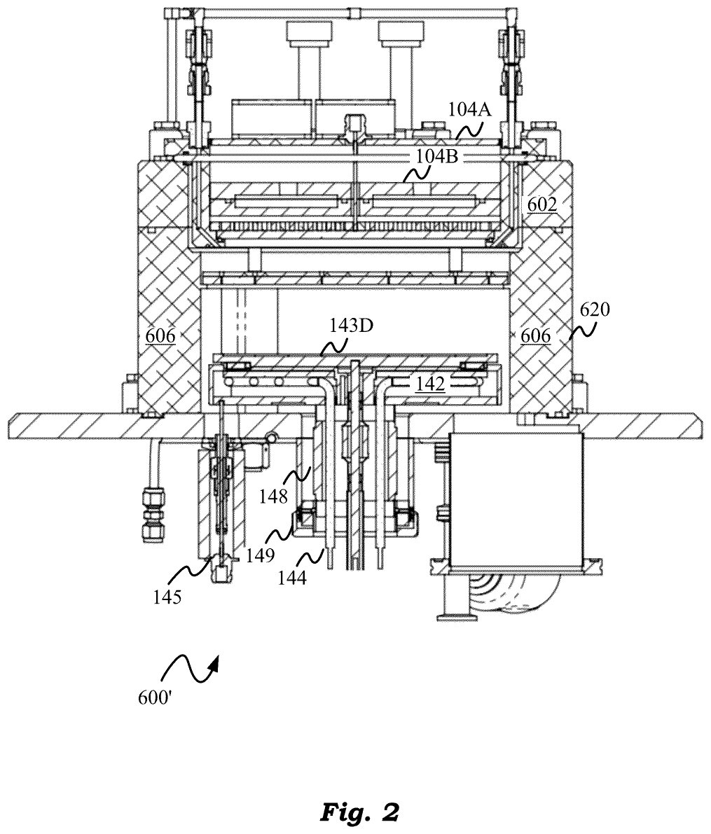

The present disclosure provides techniques for performing atomic layer etching (ALE) and atomic layer deposition (ALD) in a single reactor/chamber without changing its hardware configuration. Such a reactor may be referred to herein as an ALE-ALD or an ALE/ALD reactor. Present embodiments advantageously employ plasma for activation/excitation of various chemical species. Hence, the instant reactor may also be referred to as a plasma-enhanced/activated ALE-ALD or PEALE-PEALD reactor. FIG. 1 and FIG. 2 provide two examples of such a reactor. Let us take advantage of these drawing figures in order to understand the present technology.

To facilitate the below explanation, the reader is referred to the teachings of U.S. Pat. No. 9,972,501 B1 and U.S. Pat. No. 11,087,959 B2, which are incorporated by reference herein, and the associated explanation for the plasma-enhanced ALD (PEALD) reactor as well as the hybrid PEALD and plasma-enhanced chemical vapor deposition (PECVD) reactors provided therein. Even though the below teachings advantageously employ plasma where needed to activate various chemical specifies during the PEALE and PEALD phases of the overall operation, we may simply refer to these phases/processes as just ALE and ALD for brevity.

The hybrid PEALD/PECVD reactors of FIG. 16 through FIG. 19 of the above-incorporated teachings with some key modifications in design and process/usage are employed in the below ALE-ALD embodiments. More specifically, FIG. 1 shows hybrid PEALD/PECVD reactor 500 of FIG. 16 of the above-incorporated teachings albeit with a key modification. As such, the reactor of FIG. 1 is marked by the reference numeral 500′. Similarly, FIG. 2 shows hybrid PEALD/PECVD reactor 600 of FIG. 18 of the above-incorporated teachings albeit with a key modification. As such, the reactor FIG. 2 is marked by reference numeral 600′.

The key difference between instant reactors 500′/600′ and reactors 500/600 of the above-incorporated teachings is that platen 143D is not rotated. This is because the present embodiments do not employ CVD/PECVD at all. In reactors 500/600of the above-incorporated teachings, platen 143D was rotated in order to maintain uniformity of the PECVD layer. Since there is no PECVD in the present embodiments, the platen is not rotated. As will be explained, the nucleation of reactive sites on substrate 140 by the modification gas is driven by the self-limiting nature of the nucleation reaction and is based on the availability of reactive sites. Therefore, rotating the platen will not affect the quality of the nucleated layer.

As a result, the rotating elements of reactors 500/600 have been removed from reactors 500′ /600′ of FIG. 1/FIG. 2. More specifically, FIG. 1 does not have rotating shaft 524A of reactor 500 of the above-incorporated teachings. Similarly, reactor 600′ does not have the rotating elements and specifically rotating shaft 524A, rotary feed-through 524B and rotating motor 524C of reactor 600 of the above-incorporated teachings. For clarity, not all the elements from reactors 500 and 600 of the above-incorporated teachings may be explicitly marked in reactors 500′ and 600′of FIG. 1 and FIG. 2 respectively, but are presumed to exist. Similarly, the explanation and teachings provided for the various elements of reactors 500/600 apply to the common elements of reactors 500′/600′ and those will not be repeated here for brevity.

After having learned the similarities and key differences between instant reactors 500′/600′ and reactors 500/600, let us now understand the present ALE-ALD embodiments based on the instant principles in great detail. For this purpose, we will continue to take advantage of the teachings already provided in the above-incorporated references, specifically in relation to reactors 500/600.

According to the chief aspects, an ALE phase of the instant ALE-ALD operation is performed first, in order to “clean” the substrate/wafer prior to commencing the ALD phase. Explained further, there are impurities such as oxides on the surface of the substrate that would affect the quality the ALD layer deposited during the ALD phase. Such oxides may be various oxides of silicon or any other chemical species. The native oxide is primarily SiO2 although it may also contain other oxides or impurity layers. We will simply refer to such impurity layers as the surface layer that is unwanted and to be removed in the below disclosure. More generally, the term ‘surface layer’ as used herein refers to any layer, film, residue, deposit, or accumulation on the surface of a substrate, including but not limited to native oxides, adsorbed molecular species, metallic impurities, polymer films, plasma-damaged layers or naturally formed films.

It is important to clean the surface by removing/etching the surface layer and to bring the surface to its virgin or pristine condition that is ideally suited for ALD. Exemplarily, the ALD phase deposits Si3N4 although it may deposit any other suitable film as provided in the above-incorporated teachings. PEALD in the instant design is performed according to the teachings already provided in the above-incorporated references and at least in reference to reactors 500 and 600 taught in relation to FIG. 16-19 as well as reactor 100 of FIG. 2-6.

We will therefore focus primarily on the ALE phase of the present overall operation according to the instant principles. As noted above, a key advantage of the present design is that both the ALE and ALD phases can be performed in the same reactor. This means that one does not need to “break the vacuum” by moving the substrate from an ALE chamber to an ALD chamber as in the techniques of the prior art. Such manual interruption/intervention of the prior art reduces the process efficiency and potentially exposes the substrate to re-oxidization.

Based on the above-incorporated teachings, the configuration of the present hybrid reactor may be altered by computer-generated signals. The computer-based control software is thus used to control the electrical and RF switches for controlling the flow of electrical and RF signals to various components of the reactor. Per present explanation, such components include ICP source 104A, metal plate 522A and platen 143D. Moreover, the control software is also used to turn on/off the flow of agents/gases to the instant chamber via its various feed-through lines and ports. All such configuration changes do not cause any change in the hardware or mechanical configuration of the instant hybrid reactor.

As a result of the configurable design of the reactor, two sets of ALE embodiments are supported. In the first set of the ALE embodiments, both the modification and the removal/etching steps of ALE are performed with the aid of plasma. As such, this first set of embodiments are also referred to as mode A PEALE or just mode A ALE of the present design. However, the present design also provides another set of embodiments in which plasma is only employed in the modification step, but not in the removal step. As such, these second set of embodiments are also referred to as mode B PEALE or just mode B ALE. Let us now understand these mode A and mode B embodiments in great detail.

### Mode A ALE

According to the chief aspects, a modification or modifying gas activated in argon (Ar) ICP plasma is sent in to the chamber during the first step i.e. the modification step of the ALE phase. The modification step is carried out for a desired duration, exemplarily 4 seconds. Preferably, the modification gas is carbon tetrafluoride (CF4). Alternatively, the modification gas is carbon tetrachloride (CCl4), although it may be any other suitable modification gas/agent afforded by the design.

More specifically, let us now refer to reactor 600′ of FIG. 2 with the rear perspective view shown in the dotted-and-dashed lines as well as the associated explanation of its various elements in the above-incorporated teachings. According to the instant principles, CF4 gas along with argon (Ar) gas are sent via lines 126A and ports 126B, and then line 106A and ports 106B and 106C to ICP plasma source 104A. During this step, a radio frequency (RF) signal is provided to ICP source 104A and specifically to its RF input port 104C. We refer to this RF signal to the ICP source as the first ICP RF signal. Preferably, the first ICP RF signal has a frequency of 13.56 MHz. Exemplarily, the ICP RF signal has a power in the range of 150 watts (W) to 1000 watts i.e. 150-1000 W. Further, no RF signal is applied to metal plate 522A via RF port 504 during the modification step.

As a result of the soft or low-pressure Ar plasma thus obtained in upper portion 602 of reactor 600, fluorine radicals from CF4 are activated and sent through aligned holes 522B and 523B of metal plate 522A and ceramic plate 523A respectively. These activated fluorine radicals then enter the lower portion 620 and specifically the process volume around substrate 140 and nucleate on its surface. Exemplarily, the duration of this nucleation or modification step of the ALE phase is 4 seconds. The modification results in the formation SiF4 on the substrate. This is the case when CF4 is used as the modification gas. Alternatively, if CCl4 is use as the modification gas/agent, the nucleated layer obtained is SiCl4.

Subsequently, a removal/etching step of ALE is commenced. The removal step is also performed for a desired duration, exemplarily 4 seconds. During the removal step, the above-described first ICP RF signal to ICP source 104A is turned off and a low-power RF signal is applied to metal plate 522A via port 504. In addition, a low power RF signal or bias is also applied to the platen via RF port 145. Exemplarily, the above low-power RF signals have substantially 100 W of power and are at a frequency of 13.56 MHz. They may be the same low-power RF signal or different low-power RF signals with different frequencies and powers. These low-power RF signals preferably have RF power substantially in the range of 20 W to 100 W, although their powers may be selected to fit the needs of various applications.

Now, simultaneously with these RF signals, Ar gas is pulsed to ICP source 104A, however no modification gas/agent is supplied to the ICP source during this removal step. The resultant pulsed low-density Ar plasma ions in the process volume, sputter or remove the nucleated layer off the surface of substrate 140. Exemplarily, the nucleated layer is SiF4 or alternatively SiCl4 or still alternatively any other nucleated layer. Explained further, the plasma-enhanced/activated pulsed Ar gas ions sputter off or remove the nucleated layer that had been deposited in the modification step explained above. This process removes or reduces the thickness of the surface layer present on the surface.

The above two steps of the modification/nucleation of the substrate and the etching of SiF4/SiCl4 or another resultant nucleated layer from the substrate are repeated in sequence a number of times or cycles until a desired thickness/thinness of the surface layer is achieved. The cycle-time of the mode A ALE is the sum of the above-mentioned durations of the modification and removal steps.

After the ALE phase of the operation and after the surface layer has been reduced to sufficiently acceptable thickness/thinness level, PEALD phase is commenced. For this purpose, it is ensured that the low-power RF signals to metal plate 522A and to platen 143D are first switched off. However, ICP source 104A is now again provided an ICP RF signal. This second ICP RF signal may the same as the first ICP RF signal or a different ICP RF signal.

Preferably, the second ICP RF signal is given maximum or full power for forming high-density plasma and for maximal activation of species for ALD. As noted above, the rest of the PEALD phase is performed as per the above-incorporated teachings.

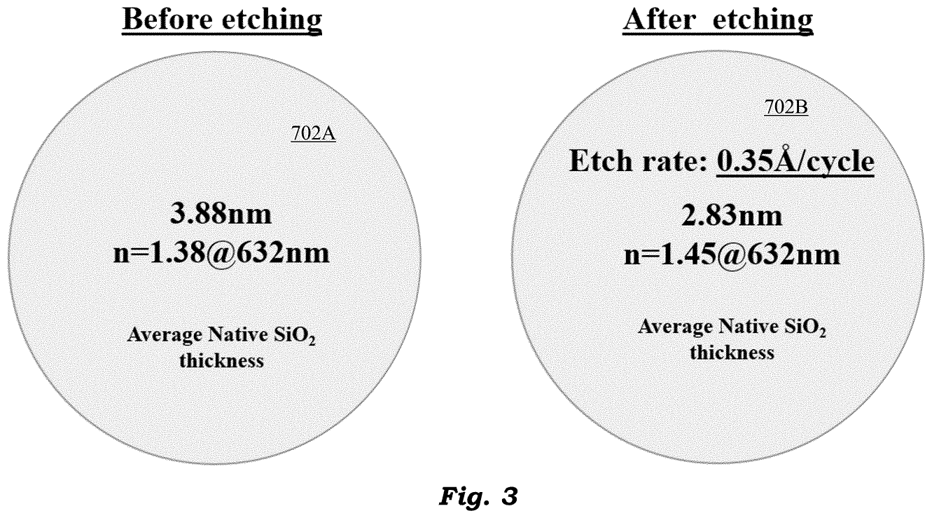

Exemplarily, the surface layer/SiO2 layer is reduced by 0.35 Angstroms/cycle by performing above-taught ALE phase. FIG. 3 shows the results of an exemplary experiment. More specifically, circle 702A of FIG. 3 conceptually represents a substrate/wafer before the ALE phase i.e. when there is native oxide still present on the surface and when the surface is not in a pristine/virgin state for ALD to be performed on it. As shown in the figure, at this point the average thickness of the native oxide layer is 3.88 nanometers (nm) with a refractive index of 1.38 as measured using a 632 nm wavelength light (red light, typical of an He—Ne laser). These measurements are exemplarily done via X-ray Photoelectron Spectroscopy (XPS).

In comparison, as shown by circle 702B, after performing 30 cycles of ALE and specifically its two modification and removal/etching steps in sequence as described above, the average thickness of the native oxide layer is reduced to 2.83 nm. The etch rate of this experiment is 0.35 Angstroms/cycle as shown. The refractive index of the thinner native oxide layer is now 1.45 using 632 nm light as noted in circle 702B. The various parameters of the above experiment are provided below. As noted below, the present design is able to operate at very low pressures.

### Parameters

Gases used:
   Step 1—Modification: CF4 and Ar with ICP plasma—4 seconds
   Step 2—Removal/Etching: Ar with metal plate plasma—4 seconds.
Cycle-time: 4 seconds+4 seconds=8 seconds
RF Power:
   ICP: 200 W
   Metal Plate: 100 W
Pressure: 0.4 Torr-0.6 Torr
No. of cycles: 30

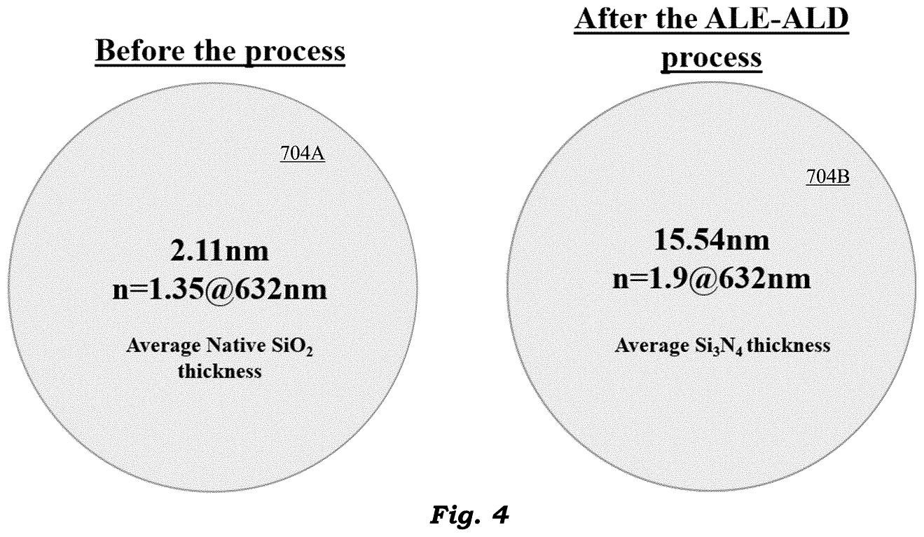

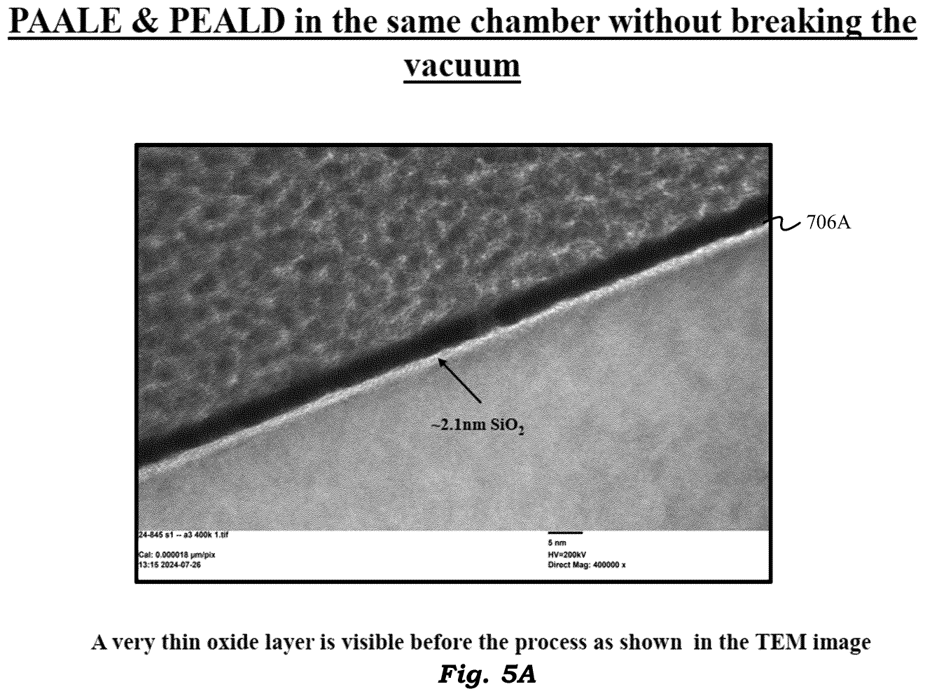

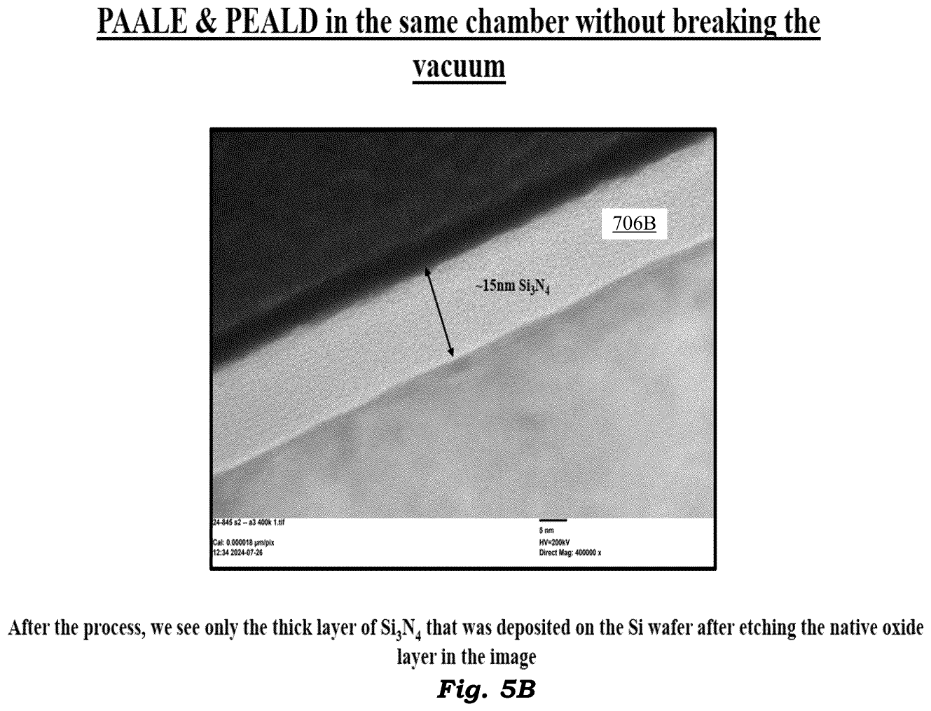

The results of another experiment are shown in FIG. 4. As noted in circle 704A, the average thickness of the native oxide layer is reduced to 2.11 nm using the above ALE techniques and then the ALD phase is commenced per the above-incorporated teachings. In the ALD phase, Si3N4 is deposited, bringing the average thickness of the deposited layer to 15.54 nm with a refractive index of 1.9 as shown. FIG. 5A is a Transmission Electron Microscopy (TEM) image showing a cross-sectional view of the native oxide layer 706A of about 2.11 nm thickness before the above-described ALE phase. In comparison, FIG. 5B presents a TEM image showing a cross-sectional view of a Si3N4 layer 706B of about 15 nm thickness. This layer is deposited in the PEALD phase based on the above-incorporated teachings, and after native oxide layer 706A of FIG. 5A had been removed using the above-described ALE phase/process. The operational parameters of the above experiment are provided below:

### Parameters

PEALE
   Gases used
      Step 1—Modification: CF4 and Ar with ICP plasma—4 seconds
      Step 2—Removal/Etching: Ar with metal plate plasma—4 seconds
   Cycle-time: 4 seconds+4 seconds=8 seconds
   RF Power
      ICP: 200 W
      Metal Plate: 25 W
   Platen temperature: 200° C.
   Pressure: 0.4 Torr-0.6 Torr
   No. of cycles: 30
PEALD
   Precursor: Bis(ethylmethylamino)silane (BEMAS*) with N2 plasma
   Temperature: 350° C.
   Cycle-time: 10 seconds
   Pulse: 60 milliseconds (ms) duration
   Power: 200 W
   Pressure: 0.5 Torr

As noted above, the present ALE embodiments of mode A of the instant ALE-ALD technology accrue great benefits by having both the ALE and ALD phases be performed in same reactor 600′, without breaking the vacuum. However, since there is still ion plasma present around substrate 140 during the ALE phase, the substrate as such is not fully protected from possible ion bombardment. In other words, damage to the device being manufactured/fabricated may still occur. This gives rise to our second set of embodiments of the present design i.e. mode B ALE embodiments.

Both the systems and process or reactors 500′/600′ of the present technology bear at least the following important differences as compared to the systems and process of the hybrid reactors 500 and 600 of the above-incorporated teachings. While the above-incorporated references provide the idea of ALE in the same hybrid reactor, there are no teachings for providing an RF bias to the platen and to the substrate during ALE as provided in the present mode A ALE embodiments of the instant ALE-ALD design. Recall from above that during the removal step of ALE, the first ICP RF signal to ICP source 104A is turned off and at the same time low-power RF signals are provided to metal plate 522A as well as platen 143D.

On the other hand, the RF bias to platen 143D in the above-incorporated teachings is provided for stress-management of the PECVD layers, and not for energizing plasma during the removal/etching step of ALE as provided above. The RF bias of the incorporated teachings is provided during the PECVD phase when chemical vapor deposition of the species takes place. In the present embodiments, there is no PECVD phase. In contrast to the deposition of species, it is for/during the removal of the species that the RF signal is provided to the platen in the present embodiments. This is another stark contrast in the systems and processes of the present embodiments to those of the above-incorporated teachings.

### Mode B ALE

Per above, it is desirable to entirely eliminate plasma from the removal/etching step the ALE phase. Recall from the teachings of the above-incorporated references, that the ALD phase neutralizes or eliminates the damaging effects of plasma around the substrate by grounding metal plate 522A. Therefore, a combined ALE-ALD design would eliminate plasma from both the ALE and ALD phases and in the same reactor. Such an innovative design comprises the present mode B ALE embodiments.

In order to accomplish this objective, a modification step is carried out for a desired duration similarly to the embodiments of mode A taught above. In other words, activated fluorine atoms with Ar plasma are used for nucleation. Exemplarily, the duration of the modification step is 3 seconds. However, during the subsequent removal/etching step, trimethylaluminum (Al(CH₃)₃ or TMA) is pulsed into the process volume and without providing any RF signal to ICP source 104A, metal plate 522A and platen 143D. The process is performed in the thermal regime only at a conveniently low temperature of about 200° C. of the platen. In other words, in the present embodiments, no RF power is provided either to ICP source 104A, or to metal plate 522A or to platen 143D during the removal/etching step of the ALE phase/process. TMA is sent to the chamber directly from below or through the side of the process volume and is activated not by plasma but only thermally. The removal step is also carried out for a desired duration, exemplarily 3 seconds. The cycle-time of the mode B ALE is the sum of the above-mentioned durations of the modification and removal steps.

The chamber is again operated in a cyclic manner until a desired thickness/thinness of the surface layer has been achieved. After the ALE phase of the operation and after the surface layer has been reduced to sufficiently acceptable thickness/thinness level, PEALD phase is commenced. For this purpose, ICP source 104A is now again provided with either the same ICP RF signal or a different ICP RF signal. As noted above, the rest of the PEALD phase is performed as per the above-incorporated teachings.

One exemplary experiment employs 3 seconds of fluorine-based modification followed by 3 seconds of TMA-based etching for exemplarily up to 50 cycles. Data shows that SiO2 compounds (native oxide) are now reduced from 86% to 21% based on the instant design. The parameters used in the experiment are given below:

Parameters used
Gases used
   Step 1: CF4 and Ar with ICP plasma—3 seconds
   Step 2: TMA pulsing with N2 carrier gas—3 seconds
Cycle-time: 3 seconds+3 seconds=6 seconds
Power: 200 W ICP
Platen temperature: 200° C.
Pressure: 0.4 Torr-0.6 Torr
No. of cycles: 50

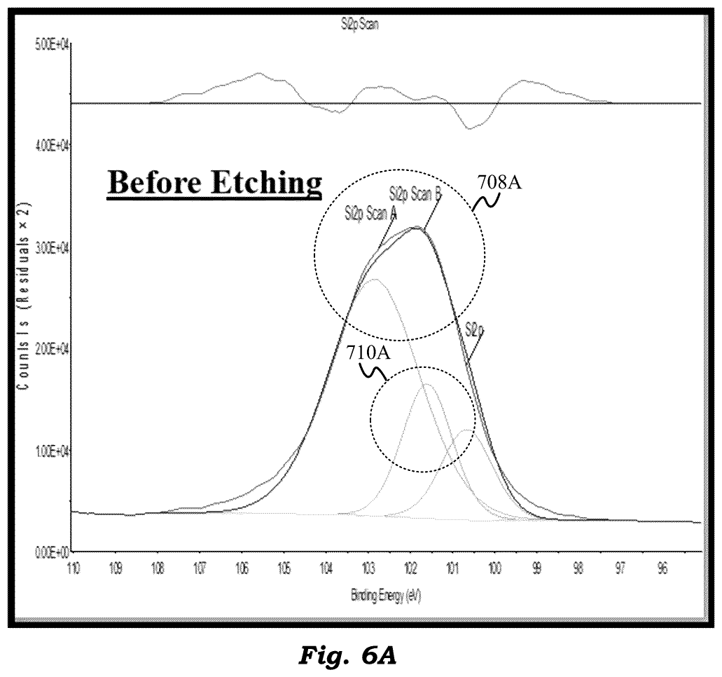

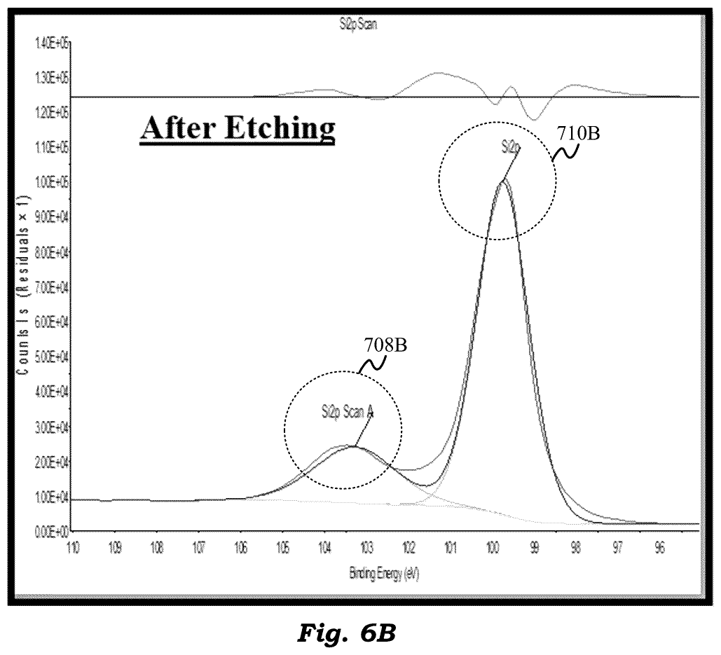

FIG. 6A and FIG. 6B show XPS data from the experiment confirming the above results. More specifically, the graphs of FIG. 6A-B show the height of curves 708A-B as measured on the y-axis for about 103 electron volts (eV) of binding energy on the x-axis. This value of binding energy is representative of SiO2. The graphs of FIG. 6A-B also show the height of curves 710A-B as measured on the y-axis around 100 eV of binding energy on the x-axis. That value of binding energy is representative of pure Si. From curves 708A and 708B shown in FIG. 6A and FIG. 6B respectively, it is apparent that the height of SiO2 curves 708 goes down from their pre-etching levels shown in FIG. 6A to their post-etching levels shown in FIG. 6B as measured on the y-axis.

In comparison, the height of Si curves 710 stays the same in FIG. 6A-B as measured on the y-axis. A person skilled in the art of reading and interpreting XPS data will readily see that the reduction in the height of curves 708A-B shown in FIG. 6A-B conforms to the reduction of native oxide from 86% shown in FIG. 6A to 21% shown in FIG. 6B.

Both the systems and process of the present mode B embodiments performed in reactors 500′/600′ of FIG. 1/FIG. 2 bear at least the following important differences as compared to the systems and processes of hybrid reactors 500/600 of the above-incorporated teachings. While the above-incorporated references provide the idea of ALE in the same hybrid reactor, there are no teachings for completely eliminating plasma in the process volume around the substrate during ALE as provided in the above mode B ALE embodiments of the instant ALE-ALD design. Per above, the etching/removal step of the instant mode B ALE embodiments is facilitated by pulsing TMA under thermal regime only. In contrast to the present embodiments, the hybrid PEALD/PECVD technology of the above-incorporated teachings employs plasma for the activation of species both during the PEALD and PECVD phases of its operation.

Moreover, in the above-incorporated teachings, the platen was rotated in order to maintain uniformity of the PECVD layer. Since there is no PECVD in the present technology, the platen is not rotated. The nucleation of reactive sites on the substrate by the modification gas is driven by the self-limiting nature of the reaction and is based on the availability of the reactive sites. As such, rotating the platen does not affect the quality of the nucleated layer and hence rotational elements and steps are eliminated from the present design. This is another key distinction of the present embodiments over the incorporated teachings.

Thus, as a result of the above design, one can perform both ALE and ALD in the same dual-purpose/hybrid reactor and without the possibility of ion damage throughout the entire ALE-ALD operation as afforded by the above mode B ALE design. Alternatively, one can also perform mode A ALE while being able to perform the ALE-ALD in a single hybrid reactor of the above teachings. One can perform either of the above-taught ALE-ALD operations in reactors 500′ and 600′ by using systems and processes distinct and different from reactors 500 and 600 of the above-incorporated teachings as discussed above.

Furthermore, the instant hybrid reactor can also be used to perform selective ALE where selective chemical species are deposited on just the defects on the substrate and then later etched off. By using the present design, one can thus remove defectivity/defectivities from the substrate and bring it to a pristine/virgin condition for further downstream processing, including ALD.

In view of the above teaching, a person skilled in the art will recognize that the apparatus and methods of invention can be embodied in many different ways in addition to those described without departing from the principles of the invention. Therefore, the scope of the invention should be judged in view of the appended claims and their legal equivalents.

What is claimed is:

1. A method of performing atomic layer etching (ALE) and atomic layer deposition (ALD) in a chamber, said method comprising the steps of:
(a) placing a substrate atop a platen inside said chamber, said chamber having a planar inductively coupled plasma (ICP) source laterally affixed at its distal end from said substrate;
(b) isolating said substrate from said ICP source in said chamber by a metal plate laterally affixed above said substrate and a ceramic plate laterally affixed below said metal plate but above said substrate, said metal plate and said ceramic plate having a first plurality of holes and a second plurality of holes respectively such that each of said first plurality of holes is aligned with a corresponding hole of said second plurality of holes, wherein each of said second plurality of holes is designed to have a diameter less than two Debye lengths of a plasma generated by said ICP source above said metal plate;
(c) isolating said metal plate from an electrical ground by a ceramic ring spacer;
(d) heating said platen, thereby heating said substrate to a desired temperature; (e) performing a modification step of said ALE for a first duration by providing a first ICP radio frequency (RF) signal to said ICP source and flowing a precursor gas to said ICP source to form said plasma, and flowing a modifying gas to said ICP source so that activated radicals of said modifying gas enter through said first plurality of holes and through said second plurality of holes into a process volume around said substrate, wherein said activated radicals of said modifying gas react with a surface layer on said substrate and form a nucleated layer on said substrate, and wherein each of said precursor gas and said modifying gas comprise one or more individual chemical species;
(f) performing an etching step of said ALE for a second duration by stopping said first ICP RF signal to said ICP source, applying a first low-power RF signal to said metal plate and by applying a second low-power RF signal to said platen, and pulsing said precursor gas to said ICP source so that ions from said precursor gas sputter off said nucleated layer from said substrate in said process volume;
(g) repeating said modification step (e) and said etching step (f) in sequence until a desired thickness of said surface layer on said substrate is achieved;
(h) performing said ALD by providing a second ICP RF signal to said ICP source and continuously flowing said precursor gas to said ICP source to continuously generate said plasma, and grounding said metal plate to terminate said plasma and pulsing a metal precursor into said process volume, said metal precursor comprising one or more individual chemical species, whereby excited neutrals of said precursor gas, said metal precursor and said substrate react in a self-limiting manner to produce a substantially uniform ALD film on said substrate.

2. The method of claim 1 selecting one or more of nitrogen, argon, oxygen and hydrogen as said one or more individual chemical species in said precursor gas.

3. The method of claim 1 selecting one or more of carbon tetrachloride and carbon tetrafluoride as said one or more individual chemical species in said modifying gas.

4. The method of claim 1, wherein said ICP RF signal has power substantially in the range of 150 watts to 1000 watts and said low-power RF signal has power substantially in the range of 20 watts to 100 watts.

5. The method of claim 1 selecting said metal precursor from the group consisting of an aluminum precursor, a gallium precursor, a silicon precursor, a zinc precursor and a hafnium precursor.

6. A method of performing atomic layer etching (ALE) and atomic layer deposition (ALD) in a chamber, said method comprising the steps of:
(a) placing a substrate atop a platen inside said chamber, said chamber having a planar inductively coupled plasma (ICP) source laterally affixed at its distal end from said substrate;
(b) isolating said substrate from said ICP source in said chamber by a metal plate laterally affixed above said substrate and a ceramic plate laterally affixed below said metal plate but above said substrate, said metal plate and said ceramic plate having a first plurality of holes and a second plurality of holes respectively such that each of said first plurality of holes is aligned with a corresponding hole of said second plurality of holes, wherein each of said second plurality of holes is designed to have a diameter less than two Debye lengths of a plasma generated by said ICP source above said metal plate;
(c) isolating said metal plate from an electrical ground by a ceramic ring spacer;
(d) heating said platen, thereby heating said substrate to a desired temperature;
(e) performing a modification step of said ALE for a first duration by providing a first ICP radio frequency (RF) signal to said ICP source and flowing a precursor gas to said ICP source to form said plasma, and flowing a modifying gas to said ICP source so that activated radicals of said modifying gas enter through said first plurality of holes and through said second plurality of holes into a process volume around said substrate, wherein said activated radicals of said modifying gas react with a surface layer on said substrate and form a nucleated layer on said substrate, and wherein each of said precursor gas and said modifying gas comprise one or more individual chemical species;
(f) performing an etching step of said ALE for a second duration by stopping said first ICP RF signal to said ICP source and by pulsing trimethylaluminum (TMA) into said process volume to etch said nucleated layer;
(g) repeating said modification step (d) and said etching step (e) in sequence until a desired thickness of said surface layer on said substrate is achieved;
(h) performing said ALD by providing a second ICP RF signal to said ICP source and continuously flowing said precursor gas to said ICP source to continuously generate said plasma, and grounding said metal plate to terminate said plasma and pulsing a metal precursor into said process volume, said metal precursor comprising one or more individual chemical species, whereby excited neutrals of said precursor gas, said metal precursor and said substrate react in a self-limiting manner to produce a substantially uniform ALD film on said substrate.

7. The method claim 6, wherein said modification step has a duration of substantially 4 seconds, and wherein said etching step also has a duration of substantially 4 seconds.

8. The method of claim 7, wherein said sequence is repeated 50 times.

9. The method of claim 6, wherein said desired temperature is substantially 200° C.

10. The method of claim 6 selecting said metal precursor from the group consisting of an aluminum precursor, a gallium precursor, a silicon precursor, a zinc precursor and a hafnium precursor.

11. A system for performing atomic layer etching (ALE) and atomic layer deposition (ALD), said system comprising:
(a) a cylindrical chamber comprising an upper portion and a lower portion such that said upper portion and said lower portion are closed to obtain a sealed state of said chamber;
(b) said upper portion comprising a planar inductively coupled plasma (ICP) source laterally affixed at its distal end from said lower portion;
(c) a substrate placed atop a platen in said lower portion and heated by a platen heater to a desired temperature; and
(d) said substrate isolated from said ICP source in said chamber by a metal plate laterally affixed above said substrate and a ceramic plate laterally affixed below said metal plate but above said substrate, said metal plate isolated from an electrical ground, and said metal plate and said ceramic plate having a first plurality of holes and a second plurality of holes respectively such that each of said first plurality of holes is aligned with a corresponding hole of said second plurality of holes, and each of said second plurality of holes having a diameter less than two Debye lengths of a plasma generated above said metal plate by said ICP source;
wherein a modification step of said ALE is performed for a first duration by providing a first ICP radio frequency (RF) signal to said ICP source and flowing a precursor gas to said ICP source to form said plasma, and flowing a modifying gas to said ICP source so that activated radicals of said modifying gas enter through said first plurality of holes and through said second plurality of holes into a process volume around said substrate, wherein said activated radicals of said modifying gas react with a surface layer on said substrate and form a nucleated layer on said substrate, and wherein each of said precursor gas and said modifying gas comprise one or more individual chemical species; and
wherein an etching step of said ALE is performed for a second duration by stopping said first ICP RF signal to said ICP source, applying a first low-power RF signal to said metal plate and by applying a second low-power RF signal to said platen, and pulsing said precursor gas to said ICP source so that ions from said precursor gas sputter off said nucleated layer from said substrate in said process volume; and
wherein said modification step and said etching step are repeated in sequence until a desired thickness of said surface layer on said substrate is achieved; and
wherein said ALD is performed by providing a second ICP RF signal to said ICP source and continuously flowing said precursor gas to said ICP source to continuously generate said plasma, and grounding said metal plate to terminate said plasma and pulsing a metal precursor into said process volume, said metal precursor comprising one or more individual chemical species, wherein excited neutrals of said precursor gas, said metal precursor and said substrate react in a self-limiting manner to produce a substantially uniform ALD film on said substrate.

12. The system of claim 11, wherein one or more of nitrogen, argon, oxygen and hydrogen are selected as said one or more individual chemical species in said precursor gas.

13. The system of claim 11, wherein one or both of carbon tetrachloride and carbon tetrafluoride are selected as said one or more individual chemical species in said modifying gas.

14. The system of claim 11, wherein said ICP RF signal has power substantially in the range of 150 watts to 1000 watts and said low-power RF signal has power substantially in the range of 20 watts to 100 watts.

15. The system of claim 11, wherein said metal precursor is selected from the group consisting of an aluminum precursor, a gallium precursor, a silicon precursor, a zinc precursor and a hafnium precursor.

16. A system for performing atomic layer etching (ALE) and atomic layer deposition (ALD), said system comprising:
(a) a cylindrical chamber comprising an upper portion and a lower portion such that said upper portion and said lower portion are closed to obtain a sealed state of said chamber;
(b) said upper portion comprising a planar inductively coupled plasma (ICP) source laterally affixed at its distal end from said lower portion;
(c) a substrate placed atop a platen in said lower portion and heated by a platen heater to a desired temperature; and
(d) said substrate isolated from said ICP source in said chamber by a metal plate laterally affixed above said substrate and a ceramic plate laterally affixed below said metal plate but above said substrate, said metal plate isolated from an electrical ground, and said metal plate and said ceramic plate having a first plurality of holes and a second plurality of holes respectively such that each of said first plurality of holes is aligned with a corresponding hole of said second plurality of holes, and each of said second plurality of holes having a diameter less than two Debye lengths of a plasma generated above said metal plate by said ICP source;
wherein a modification step of said ALE is performed for a first duration by providing a first ICP radio frequency (RF) signal to said ICP source and flowing a precursor gas to said ICP source to form said plasma, and flowing a modifying gas to said ICP source so that activated radicals of said modifying gas enter through said first plurality of holes and through said second plurality of holes into a process volume around said substrate, wherein said activated radicals of said modifying gas react with a surface layer on said substrate and form a nucleated layer on said substrate, and wherein each of said precursor gas and said modifying gas comprise one or more individual chemical species; and
wherein an etching step of said ALE is performed for a second duration by switching off said first ICP RF signal to said ICP source and by pulsing trimethylaluminum (TMA) into said process volume to etch said nucleated layer from said substrate in said process volume; and
wherein said modification step and said etching step are repeated in sequence until a desired thickness of said surface layer on said substrate is achieved; and
wherein said ALD is performed by providing a second ICP RF signal to said ICP source and continuously flowing said precursor gas to said ICP source to continuously generate said plasma, and grounding said metal plate to terminate said plasma and pulsing a metal precursor into said process volume, said metal precursor comprising one or more individual chemical species, wherein excited neutrals of said precursor gas, said metal precursor and said substrate react in a self-limiting manner to produce a substantially uniform ALD film on said substrate.

17. The system claim 16, wherein said modification step has a duration of substantially 3 seconds, and wherein said etching step also has a duration of substantially 3 seconds.

18. The system of claim 17, wherein said sequence is repeated 50 times.

19. The system of claim 16, wherein said desired temperature is substantially 200° C.

20. The system of claim 16, wherein said metal precursor is selected from the group consisting of an aluminum precursor, a gallium precursor, a silicon precursor, a zinc precursor and a hafnium precursor.
